(19) United States
(12) Patent Application Publication
(10) Pub. No.: US 2025/0040235 A1
(43) Pub. Date: Jan. 30, 2025

(54) INTEGRATED CIRCUIT DEVICE AND MANUFACTURING METHOD THEREOF

(71) Applicant: Taiwan Semiconductor Manufacturing Company, Ltd., Hsinchu (TW)

(72) Inventors: Guan-Lin Chen, Hsinchu County (TW); Kuo-Cheng Chiang, Hsinchu County (TW); Jung-Chien Cheng, Tainan City (TW); Shi Ning Ju, Hsinchu City (TW); Chih-Hao Wang, Hsinchu County (TW)

(73) Assignee: Taiwan Semiconductor Manufacturing Company, Ltd., Hsinchu (TW)

(21) Appl. No.: 18/358,522

(22) Filed: Jul. 25, 2023

(51) Int. Cl. H01L 27/088; H01L 21/8234

(52) U.S. Cl. CPC H01L 27/088; H01L 21/82345; H01L 21/823481

(57) ABSTRACT

A method for manufacturing an integrated circuit device is provided. The method includes depositing an epitaxial stack comprising alternative first and second semiconductor layers over a semiconductor substrate; patterning the epitaxial stack to form first and second semiconductor fins; removing the first semiconductor layers in the first and second semiconductor fins, while leaving a first set of the second semiconductor layers in the first semiconductor fin and a second set of the second semiconductor layers in the second semiconductor fin; forming a gate dielectric layer around the first and second sets of the second semiconductor layers; depositing a gate metal layer over the gate dielectric layer; etching a recess in the gate metal layer and between the first and second sets of the second semiconductor layers, wherein the gate metal layer has a first portion below the recess; and forming a dielectric feature in the recess.

### BACKGROUND

As the semiconductor industry has progressed into nanometer technology process nodes in pursuit of higher device density, higher performance, and lower costs, challenges from both fabrication and design issues have resulted in the development of three-dimensional designs, such as a multi-gate field effect transistor (FET), including a gate-all-around (GAA) FET. In a GAA FET, all side surfaces of the channel region are surrounded by the gate electrode, which allows for fuller depletion in the channel region and results in less short-channel effects due to steeper sub-threshold current swing (SS) and smaller drain induced barrier lowering (DIBL).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-16C illustrate a method of manufacturing an integrated circuit device at various stages in accordance with some embodiments.

FIG. 17 illustrate a cross-sectional view of an integrated circuit device in accordance with some embodiments.

FIG. 18 illustrate a cross-sectional view of an integrated circuit device in accordance with some embodiments.

FIG. 19 illustrate a cross-sectional view of an integrated circuit device in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

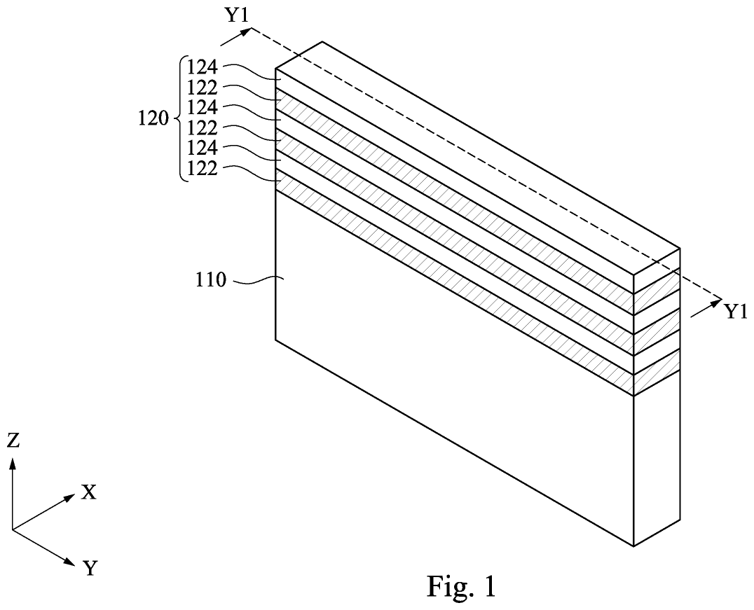

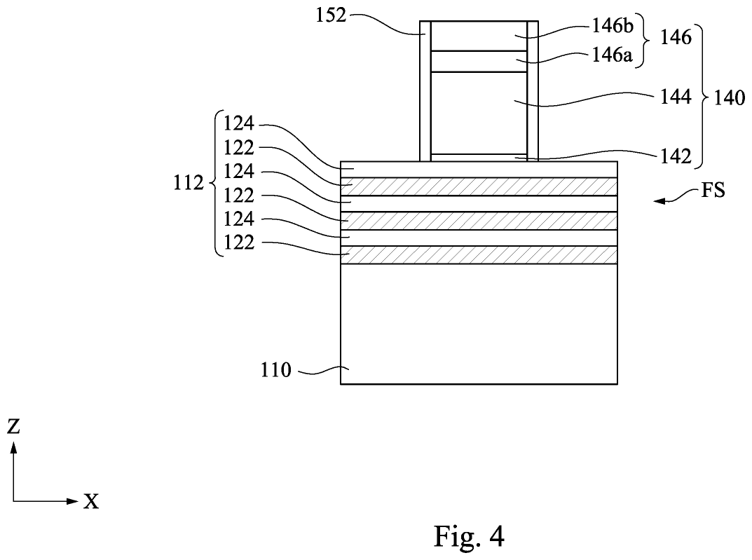

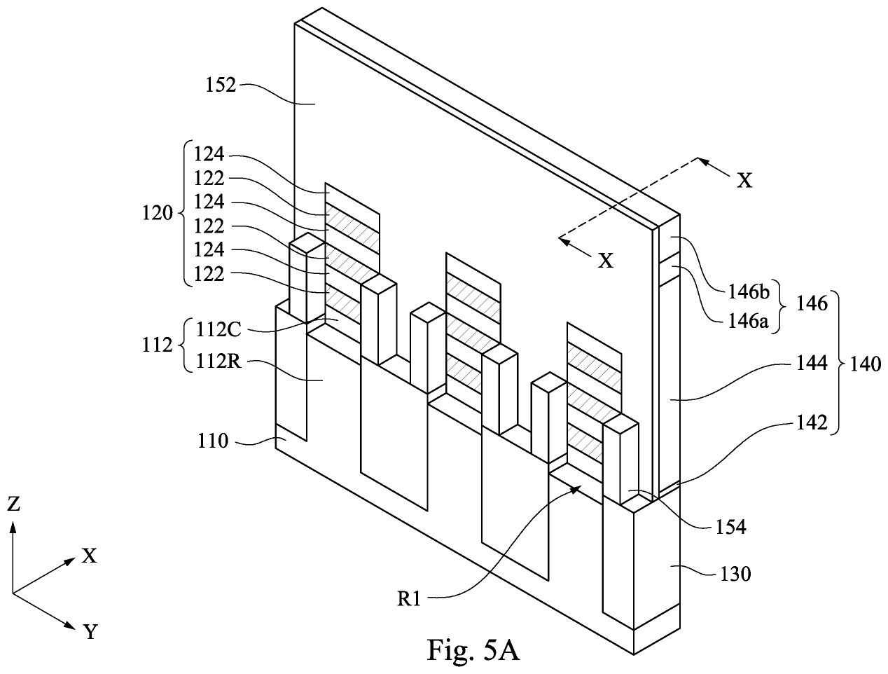

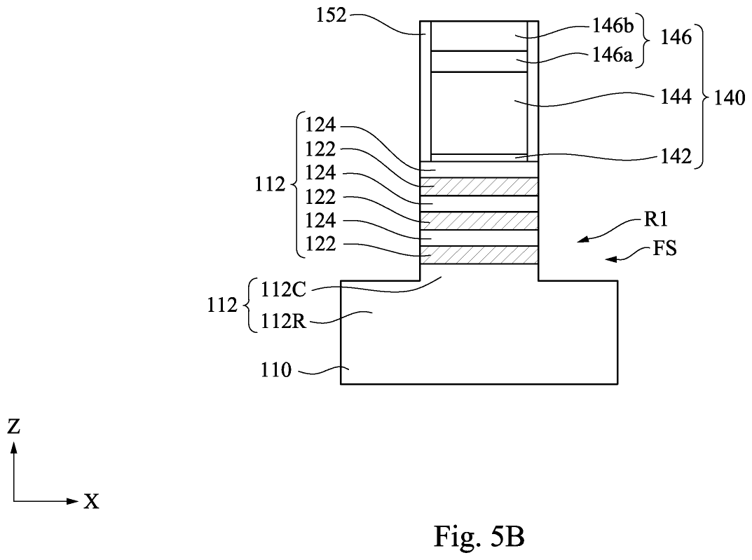

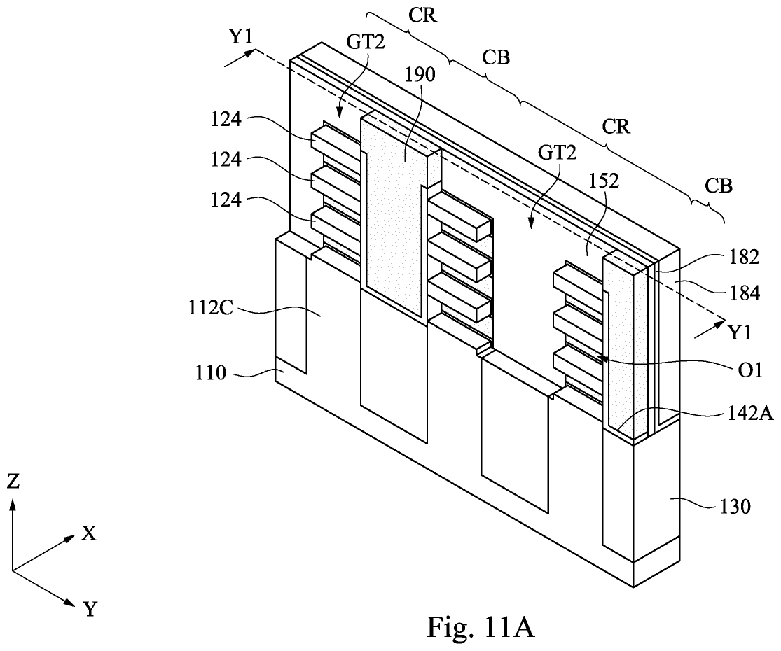

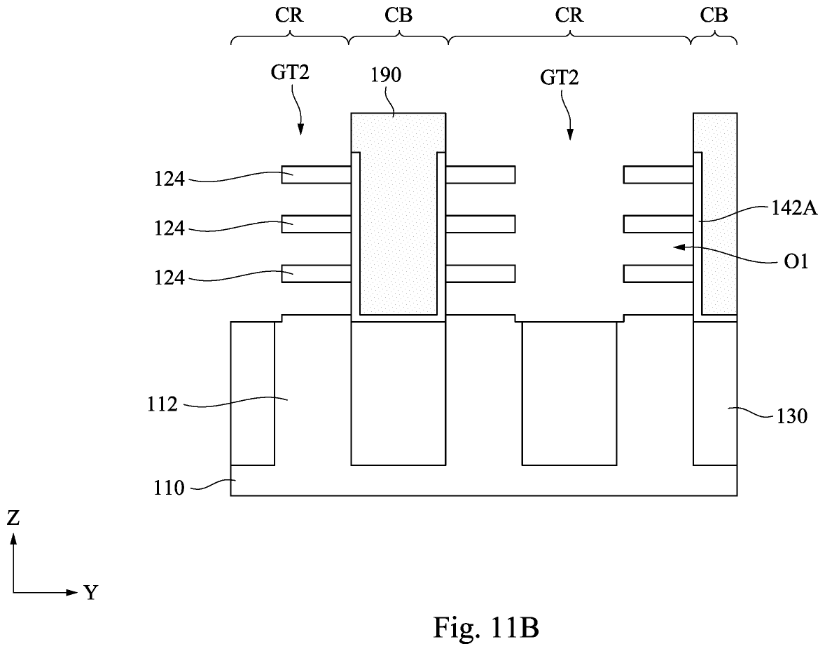

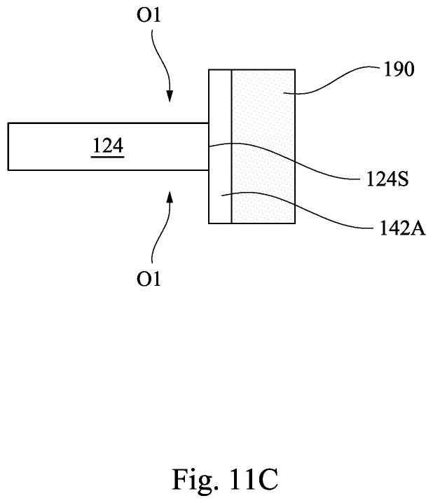

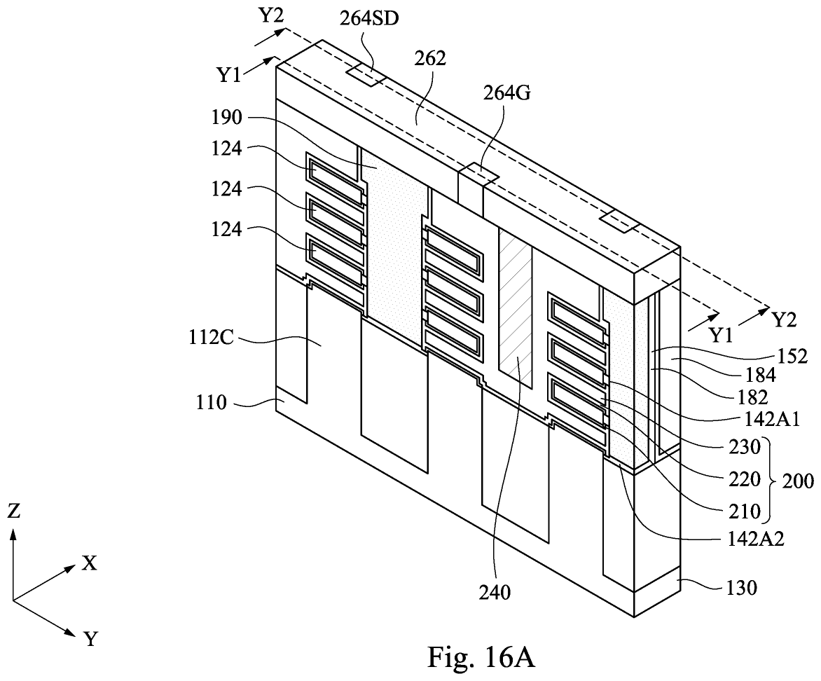

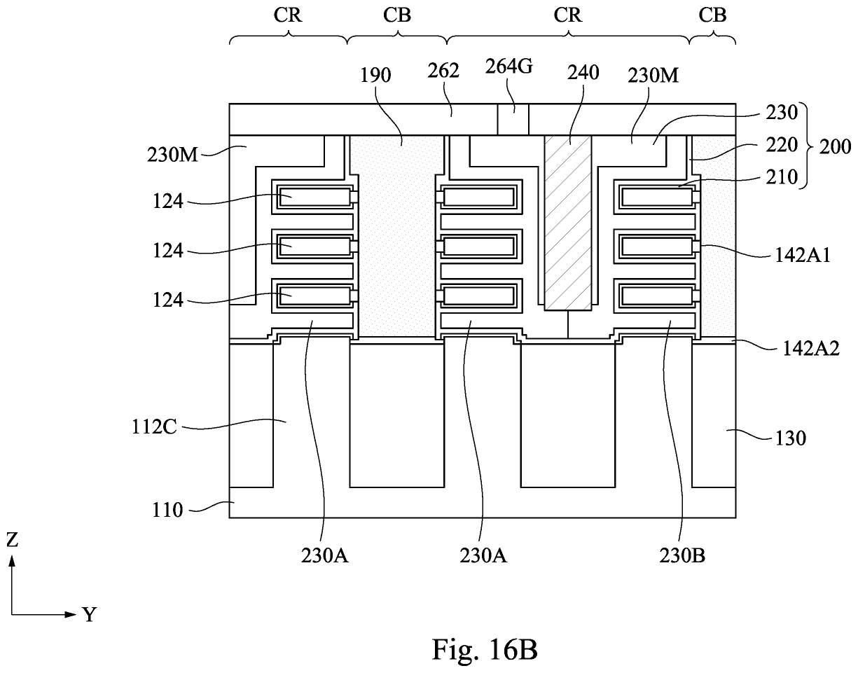

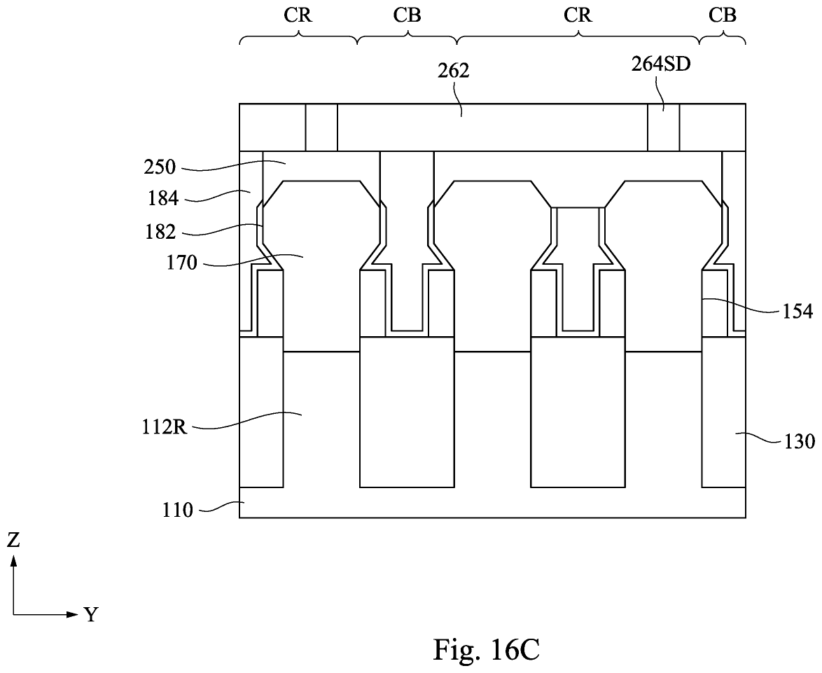

FIGS. 1-16C illustrate a method of manufacturing an integrated circuit device at various stages in accordance with some embodiments. FIGS. 1-3, 5A, 6A, 7A, 8-10, 11A, 12A, 13A, 14A, 15A, and 16A are perspective views of the integrated circuit device at various manufacturing stages in accordance with some embodiments. FIGS. 4, 5B, 6B, and 7B are cross-sectional views taken along X direction (e.g. along line X-X in FIGS. 5A, 6A, and 7A). FIGS. 11B, 12B, 13B, 14B, 15B, and 16B are cross-sectional views taken along Y direction (e.g. along line Y1-Y1 in FIGS. 11A, 12A, 13A, 14A, 15A, and 16A). FIG. 16C is a cross-sectional view taken along Y direction (e.g. along line Y2-Y2 in FIG. 16A). It is understood that additional steps may be provided before, during, and after the steps shown in FIGS. 1-16C, and some of the steps described below can be replaced or eliminated for additional embodiments of the method. The order of the operations/processes may be interchangeable.

As with the other method embodiments and exemplary devices discussed herein, it is understood that parts of the integrated circuit structure may be fabricated by a CMOS technology process flow, and thus some processes are only briefly described herein. Further, the exemplary integrated circuit structure may include various other devices and features, such as other types of devices such as additional transistors, bipolar junction transistors, resistors, capacitors, inductors, diodes, fuses, static random access memory (SRAM) and/or other logic circuits, etc., but is simplified for a better understanding of the concepts of the present disclosure. In some embodiments, the exemplary integrated circuit structure includes a plurality of semiconductor devices (e.g., transistors), including PFETs, NFETs, etc., which may be interconnected.

FIG. 1 illustrates a perspective view of an initial structure. The initial structure includes a substrate 110. The substrate 110 may be a bulk silicon substrate. Alternatively, the substrate 110 may include an elementary semiconductor, such as silicon (Si) or germanium (Ge) in a crystalline structure; a compound semiconductor, such as silicon germanium (SiGe), silicon carbide (SiC), gallium arsenic (GaAs), gallium phosphide (GaP), indium phosphide (InP), indium arsenide (InAs), and/or indium antimonide (InSb); or combinations thereof. Possible substrates 110 also include a silicon-on-insulator (SOI) substrate. SOI substrates are fabricated using separation by implantation of oxygen (SIMOX), wafer bonding, and/or other suitable methods.

An epitaxial stack 120 may be formed over the substrate 110. The epitaxial stack 120 may include epitaxial layers 122 of a first composition interposed by epitaxial layers 124 of a second composition. The first and second compositions can be different. In some embodiments, the epitaxial layers 122 are SiGe, and the epitaxial layers 124 are silicon (Si). However, other embodiments are possible including those that provide for a first composition and a second composition having different oxidation rates and/or etch selectivity. In some embodiments, the epitaxial layers 122 include SiGe and where the epitaxial layers 124 include Si, the Si oxidation rate of the epitaxial layers 124 is less than the SiGe oxidation rate of the epitaxial layers 122.

The epitaxial layers 124 or portions thereof may form nanosheet channel(s) of the multi-gate transistor. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. The use of the epitaxial layers 124 to define a channel or channels of a device is further discussed below.

It is noted that three layers of the epitaxial layers 122 and three layers of the epitaxial layers 124 are alternately arranged as illustrated in FIG. 1, which is for illustrative purposes only and not intended to be limiting beyond what is specifically recited in the claims. It can be appreciated that any number of epitaxial layers can be formed in the epitaxial stack 120; the number of layers depending on the desired number of channels regions for the transistor. In some embodiments, the number of epitaxial layers 124 is between 2 and 10.

In some embodiments, each epitaxial layer 122 has a thickness ranging from about 1 nanometers (nm) to about 10 nm, but other ranges are within the scope of various embodiments of the present disclosure. The epitaxial layers 122 may be substantially uniform in thickness. In some embodiments, each epitaxial layer 124 has a thickness ranging from about 1 nm to about 10 nm, but other ranges are within the scope of various embodiments of the present disclosure. In some embodiments, the epitaxial layers 124 of the stack 120 are substantially uniform in thickness. As described in more detail below, the epitaxial layers 124 may serve as channel region(s) for a subsequently-formed multi-gate device and the thickness is chosen based on device performance considerations. The epitaxial layers 122 in channel regions(s) may eventually be removed and serve to define a vertical distance between adjacent channel region(s) for a subsequently-formed multi-gate device and the thickness is chosen based on device performance considerations. Accordingly, the epitaxial layers 122 may also be referred to as sacrificial layers, and epitaxial layers 124 may also be referred to as channel layers.

By way of example, epitaxial growth of the layers of the stack 120 may be performed by a molecular beam epitaxy (MBE) process, a metalorganic chemical vapor deposition (MOCVD) process, and/or other suitable epitaxial growth processes. In some embodiments, the epitaxially grown layers such as, the epitaxial layers 124 include the same material as the substrate 110. In some embodiments, the epitaxially grown layers 122 and 124 include a different material than the substrate 110. As stated above, in at least some examples, the epitaxial layers 122 include an epitaxially grown silicon germanium (SiGe) layer and the epitaxial layers 124 include an epitaxially grown silicon (Si) layer. Alternatively, in some embodiments, either of the epitaxial layers 122 and 124 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the epitaxial layers 122 and 124 may be chosen based on providing differing oxidation and/or etching selectivity properties. In some embodiments, the epitaxial layers 122 and 124 are substantially dopant-free (i.e., having an extrinsic dopant concentration from about 0 cm⁻³ to about 1×10¹⁸ cm⁻³), where for example, no intentional doping is performed during the epitaxial growth process.

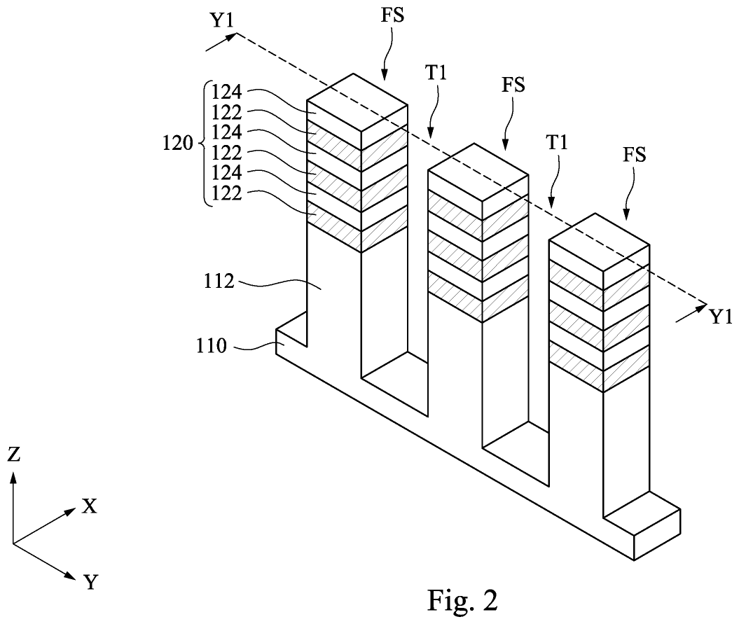

FIG. 2 illustrates formation of semiconductor fins FS extending from the substrate 110. In various embodiments, each of the fins FS includes a portion 112 of the substrate 110 and portions of each of the epitaxial layers of the epitaxial stack including epitaxial layers 122 and 124. The fins FS may be fabricated using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins FS by etching initial epitaxial stack 120 (illustrated in FIG. 1). The etching process can include dry etching, wet etching, reactive ion etching (RIE), and/or other suitable processes.

The fins FS may subsequently be fabricated using suitable processes including photolithography and etch processes. The photolithography process may include forming a photoresist layer (not shown) over the substrate 110 and layers formed thereupon, exposing the photoresist to a pattern, performing post-exposure bake processes, and developing the resist to form a patterned mask including the resist. In some embodiments, patterning the resist to form the patterned mask element may be performed using an electron beam (e-beam) lithography process or an extreme ultraviolet (EUV) lithography process using light in EUV region. The patterned mask may then be used to protect regions of the substrate 110, and layers formed thereupon, while an etch process forms trenches T1 in unprotected regions through the patterned mask, through the epitaxial stack 120, and into the substrate 110, thereby leaving the plurality of extending fins FS. The trenches T1 may be etched using a dry etch (e.g., reactive ion etching), a wet etch, and/or combination thereof. Numerous other embodiments of methods to form the fins on the substrate may also be used including, for example, defining the fin region (e.g., by mask or isolation regions) and epitaxially growing the epitaxial stack 120 in the form of the fins FS.

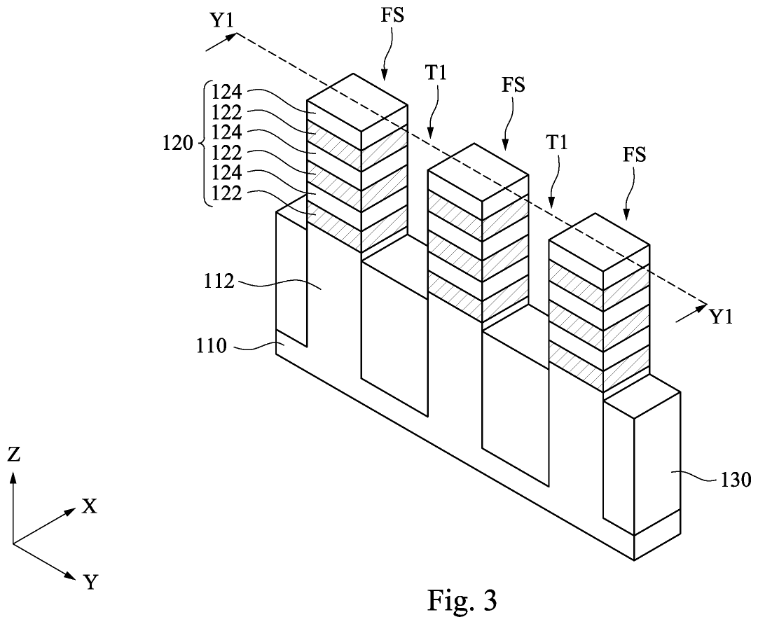

FIG. 3 illustrates formation of an isolation structure 130 in the trenches T1 between the fins FS. By way of example and not limitation, a dielectric layer is first deposited over the substrate 110, filling the trenches T1 with the dielectric material. In some embodiments, the dielectric layer may include silicon oxide, silicon nitride, silicon oxynitride, fluorine-doped silicate glass (FSG), a low-k dielectric, combinations thereof, and/or other suitable materials. In various examples, the dielectric layer may be deposited by a CVD process, a subatmospheric CVD (SACVD) process, a flowable CVD process, an ALD process, a physical vapor deposition (PVD) process, and/or other suitable processes. In some embodiments, after deposition of the dielectric layer, the integrated circuit structure may be annealed, for example, to improve the quality of the dielectric layer. A chemical mechanical polishing (CMP) process may be performed to thin and planarize the deposited dielectric layer, remaining portions of the dielectric layer form the isolation structures 130 between the fins FS. The isolation structures 130 are recessed by an etch back process, thereby providing the fins FS having exposed sidewalls extending above the etched back isolation structure 130. The etched back isolation structures 130 may be referred to as shallow trench isolation (STI) structures. As shown in the figures, a top surface of the fins FS may be higher than a top surface of the isolation structure 130. In some embodiments, the recessing process may include a dry etching process, a wet etching process, and/or a combination thereof. A recessing depth may be controlled (e.g., by controlling an etching time) so as to result in a target height of the exposed upper portion of the fins FS. In the illustrated embodiments, the target height exposes each of the epitaxial layers 122 and 124 of the epitaxial stack 120 in the fins FS. In some embodiments, the isolation structures 130 may include a multi-layer structure, for example, having one or more liner layers. In the context, the isolation structure 130 may define oxide defined (OD) regions (e.g., fins FS).

FIG. 4 illustrates formation of gate structures 140. In some embodiments, the gate structures 140 are dummy (sacrificial) gate structures that are subsequently removed. Thus, in some embodiments using a gate-last process, the gate structures 140 are dummy gate structures and will be replaced by the final gate structures at a subsequent processing stage of the integrated circuit device. In particular, the dummy gate structures 140 may be replaced at a later processing stage by a high-k dielectric layer (HK) and metal gate electrode (MG) as discussed below. In some embodiments, the dummy gate structures 140 are formed over the substrate 110 and are at least partially disposed over the fins FS. The portion of the fins FS underlying the dummy gate structures 140 may be referred to as the channel region. The dummy gate structures 140 may also define a source/drain (S/D) region of the fins FS, for example, the regions of the fin FS adjacent and on opposing sides of the channel region.

In the illustrated embodiments, the formation of the gate structures 140 first forms a dummy gate dielectric layer 142 over the fins FS. In some embodiments, the dummy gate dielectric layer 142 may include SiO₂, silicon nitride, a high-k dielectric material and/or other suitable material. In various examples, the dummy gate dielectric layer 142 may be deposited by a CVD process, a subatmospheric CVD (SACVD) process, a flowable CVD process, an ALD process, a PVD process, or other suitable process. By way of example, the dummy gate dielectric layer 142 may be used to prevent damages to the fins FS by subsequent processes (e.g., subsequent formation of the dummy gate structure). Subsequently, the formation of the gate structures 140 forms a dummy gate electrode layer 144 and a hard mask 146 which may include multiple layers (e.g., a nitride layer 146a and an oxide layer 146b).

In some embodiments, the dummy gate structure 140 is formed by various process steps such as layer deposition, patterning, etching, as well as other suitable processing steps. Exemplary layer deposition processes include CVD (including both low-pressure CVD and plasma-enhanced CVD), PVD, ALD, thermal oxidation, e-beam evaporation, or other suitable deposition techniques, or combinations thereof. In forming the gate structure for example, the patterning process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods. In some embodiments, the dummy gate electrode layer 144 may include polycrystalline silicon (polysilicon). In some embodiments, the hard mask 146 includes a nitride layer 172 such as Si₃N₄ and/or silicon oxynitride and an oxide layer 174 such as SiO₂. In some embodiments, after patterning the dummy gate electrode layer 144, the dummy gate dielectric layer 142 is removed from the S/D regions of the fins FS. The etch process may include a wet etch, a dry etch, and/or a combination thereof. The etch process is chosen to selectively etch the dummy gate dielectric layer 142 without substantially etching the fins FS and the dummy gate electrode layer 144. Through the steps, the dummy gate structure 140 are formed across the semiconductor fins FS.

After the formation of the dummy gate structures 140, gate spacers 152 are formed on sidewalls of the dummy gate structures 140. For example, a spacer material layer is conformally deposited on the substrate using processes such as, CVD process, a subatmospheric CVD (SACVD) process, a flowable CVD process, an ALD process, a PVD process, or other suitable process. The spacer material layer may include a dielectric material such as silicon oxide, silicon nitride, silicon carbide, silicon oxynitride, SiCN films, silicon oxycarbide, SiOCN films, and/or combinations thereof. The spacer material layer is subsequently etched back to form the gate spacers 152. For example, an anisotropic etching process is performed on the deposited spacer material layer to expose portions of the fins FS not covered by the dummy gate structures 140 (e.g., in source/drain regions of the fins FS). Portions of the spacer material layer directly above the dummy gate structures 140 may be completely removed by this anisotropic etching process. Portions of the spacer material layer on sidewalls of the dummy gate structures 140 may remain, forming gate sidewall spacers, which are denoted as the gate spacers 152, for the sake of simplicity. In some embodiments, portions of the spacer material layer on sidewalls of the fins FS may remain, forming fin sidewall spacers, which are denoted as fin sidewall spacers 154 (shown in FIGS. 5A and 5B later), for sake of simplicity. In some embodiments, the spacer material layer includes multiple layers, and therefore the gate spacers 152 (and fin sidewall spacers 154 in FIGS. 5A and 5B) may be multi-layer structures.

Reference is made to FIGS. 5A and 5B. Portions of the semiconductor fins FS that extend laterally beyond the gate spacers 152 (e.g., in source/drain regions of the fins FS) are etched by using, for example, an anisotropic etching process that uses the dummy gate structures 140, the gate spacers 152 as an etch mask, resulting in recesses R1 into the fins FS and between corresponding dummy gate structures 140. After the anisotropic etching, end surfaces of the sacrificial layers 122 and channel layers 124 are substantially aligned with respective outermost sidewalls of the gate spacers 152, due to the anisotropic etching. In some embodiments, the anisotropic etching may be performed by a dry chemical etch with a plasma source and a reaction gas. The plasma source may be an inductively coupled plasma (ICR) source, a transformer coupled plasma (TCP) source, an electron cyclotron resonance (ECR) source or the like, and the reaction gas may be, for example, a fluorine-based gas (such as SF₆, CH₂F₂, CH₃F, CHF₃, or the like), chloride-based gas (e.g., Cl₂), hydrogen bromide gas (HBr), oxygen gas (O₂), the like, or combinations thereof. In some embodiments, the isolation structure 130 may have a higher etch resistance to the anisotropic etching process than that of the semiconductor fins FS, and thus not substantially etched.

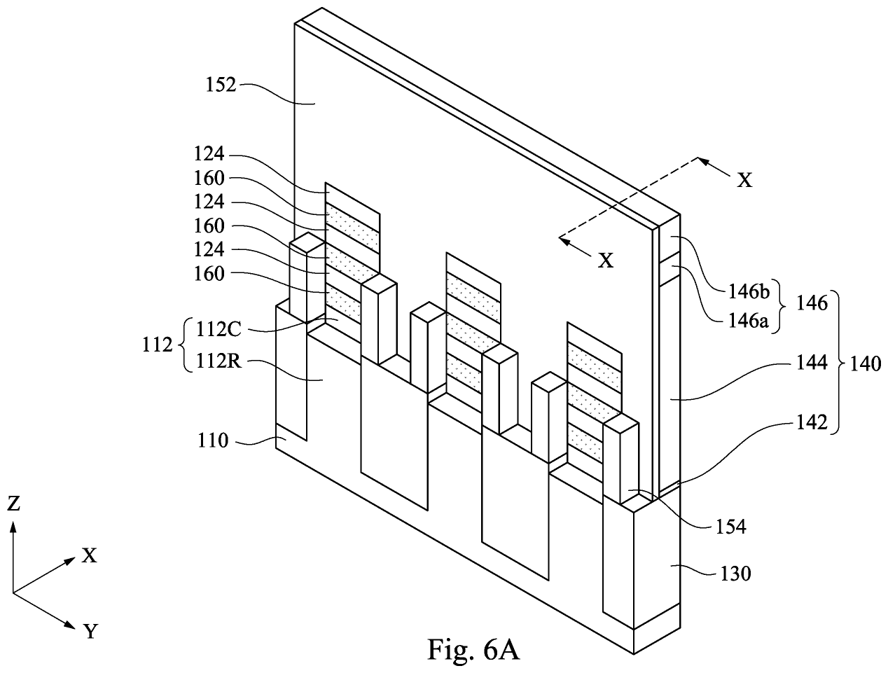

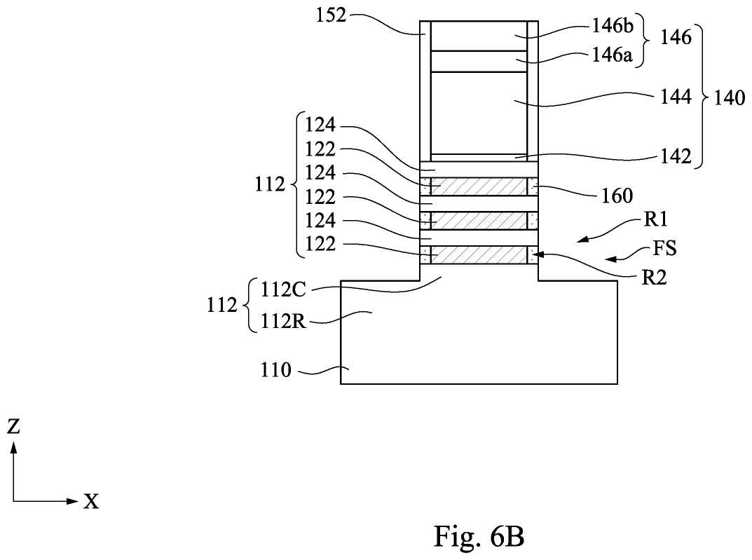

Next, referring to FIGS. 6A and 6B, the sacrificial layers 122 are laterally or horizontally recessed by using suitable etch techniques, resulting in lateral recesses R2 each vertically between corresponding channel layers 124. This step may be performed by using a selective etching process. By way of example and not limitation, the sacrificial layers 122 are SiGe and the channel layers 124 are silicon allowing for the selective etching of the sacrificial layers 122. In some embodiments, the selective wet etching includes an APM etch (e.g., ammonia hydroxide-hydrogen peroxide-water mixture) that etches SiGe at a faster etch rate than it etches Si. In some embodiments, the selective etching includes SiGe oxidation followed by a SiGeOₓ removal. For example, the oxidation may be provided by O₃ clean and then SiGeOₓ removed by an etchant such as NH₄OH that selectively etches SiGeOₓ at a faster etch rate than it etches Si. Moreover, because oxidation rate of Si is much lower (sometimes 30 times lower) than oxidation rate of SiGe, the channel layers 124 remain substantially intact during laterally recessing the sacrificial layers 122. As a result, the channel layers 124 laterally extend past opposite end surfaces of the sacrificial layers 122.

After the sacrificial layers 122 have been laterally recessed, an inner spacer material is formed to fill the recesses R2 left by the lateral etching of the sacrificial layers 122. The inner spacer material may be a low-k dielectric material (with dielectric constant lower than about 7), such as SiO₂, SiN, SiCN, or SiOCN, the like, or the combination thereof. The inner spacer material may be formed by a suitable deposition method, such as ALD. After the deposition of the inner spacer material, an anisotropic etching process may be performed to trim the deposited inner spacer material, such that only portions of the deposited inner spacer material that fill the recesses R2 left by the lateral etching of the sacrificial layers 122 are left. After the trimming process, the remaining portions of the deposited inner spacer material are denoted as inner spacers 160, for the sake of simplicity. The inner spacers 160 serve to isolate metal gates from source/drain epitaxial structures formed in subsequent processing. In the example of FIG. 6B, sidewalls of the inner spacers 160 may be vertically aligned with sidewalls of the channel layers 124. In some other embodiments, sidewalls of the inner spacers 160 are laterally set back from sidewalls of the channel layers 124.

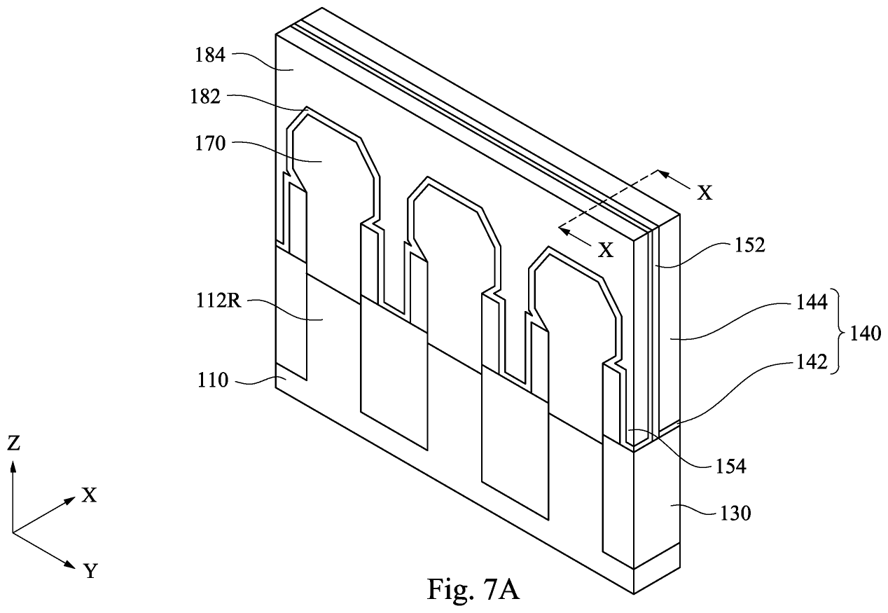

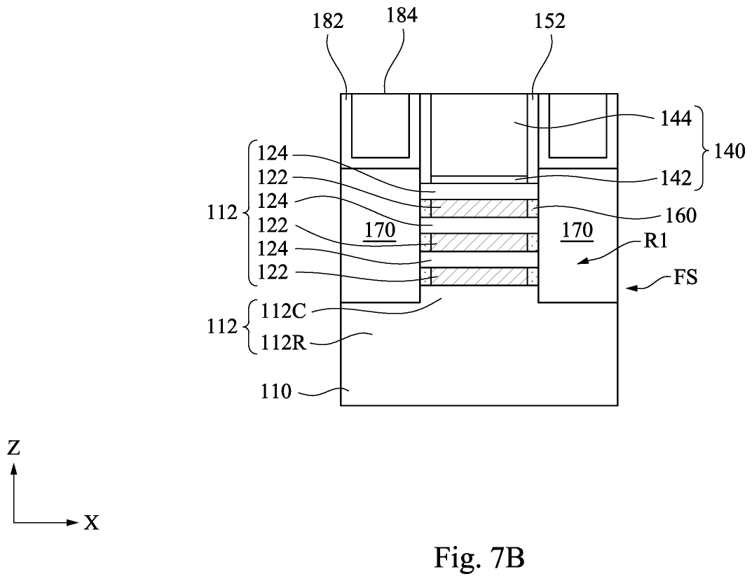

Reference is made to FIGS. 7A and 7B. After the formation of the inner spacers 160, source/drain epitaxial structures 170 are formed in the recesses R1 in the fins FS. The source/drain epitaxial structures 170 may be formed by performing an epitaxial growth process that provides an epitaxial material on the fins FS. During the epitaxial growth process, the dummy gate structures 140, the gate spacers 152, and the fin sidewall spacers 154 limit the source/drain epitaxial structures 170 to the source/drain regions in the fins FS. Suitable epitaxial processes include CVD deposition techniques (e.g., vapor-phase epitaxy (VPE) and/or ultra-high vacuum CVD (UHV-CVD)), molecular beam epitaxy, and/or other suitable processes. The epitaxial growth process may use gaseous and/or liquid precursors, which interact with the composition of semiconductor materials of the substrate 110 and the channel layers 124.

In some embodiments, the source/drain epitaxial structures 170 may include Ge, Si, GaAs, AlGaAs, SiGe, GaAsP, SiP, or other suitable material. The source/drain epitaxial structures 170 may be in-situ doped during the epitaxial process by introducing doping species including: p-type dopants, such as boron; n-type dopants, such as phosphorus or arsenic; and/or other suitable dopants including combinations thereof. If the source/drain epitaxial structures 170 are not in-situ doped, an implantation process (i.e., a junction implant process) is performed to dope the source/drain epitaxial structures 170. In some exemplary embodiments, the source/drain epitaxial structures 170 in an NFET device include SiP, while those in a PFET device include GeSnB and/or SiGeSnB.

After the formation of the source/drain epitaxial structures 170, a CESL 182 may be deposited. In some examples, the CESL 182 includes a silicon nitride layer, silicon oxide layer, a silicon oxynitride layer, and/or other suitable materials. The CESL 182 may be formed by plasma-enhanced chemical vapor deposition (PECVD) process and/or other suitable deposition or oxidation processes. An interlayer dielectric (ILD) layer 184 is then deposited over the CESL 182. In some embodiments, the ILD layer 184 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL 182. The ILD layer 184 may be deposited by a PECVD process or other suitable deposition technique. In some embodiments, after formation of the ILD layer 184, the integrated circuit device may be subject to a high thermal budget process to anneal the ILD layer 184.

After depositing the ILD layer 184, a planarization process may be performed to remove excessive materials of the CESL 182 and the ILD layer 184. For example, a planarization process includes a chemical mechanical planarization (CMP) process which removes portions of the ILD layer 184 and the CESL 182 overlying the dummy gate structures 140 and planarizes a top surface of the integrated circuit device. In some embodiments, the CMP process also removes the hard mask 146 in the dummy gate structures 140 (as shown in FIGS. 6A and 6B) and exposes the dummy gate electrode layer 144.

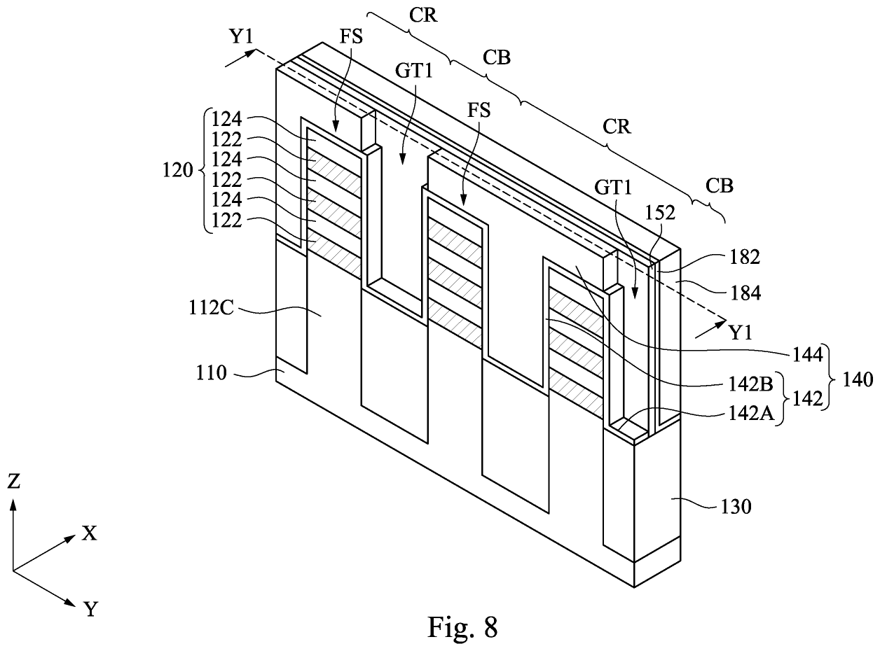

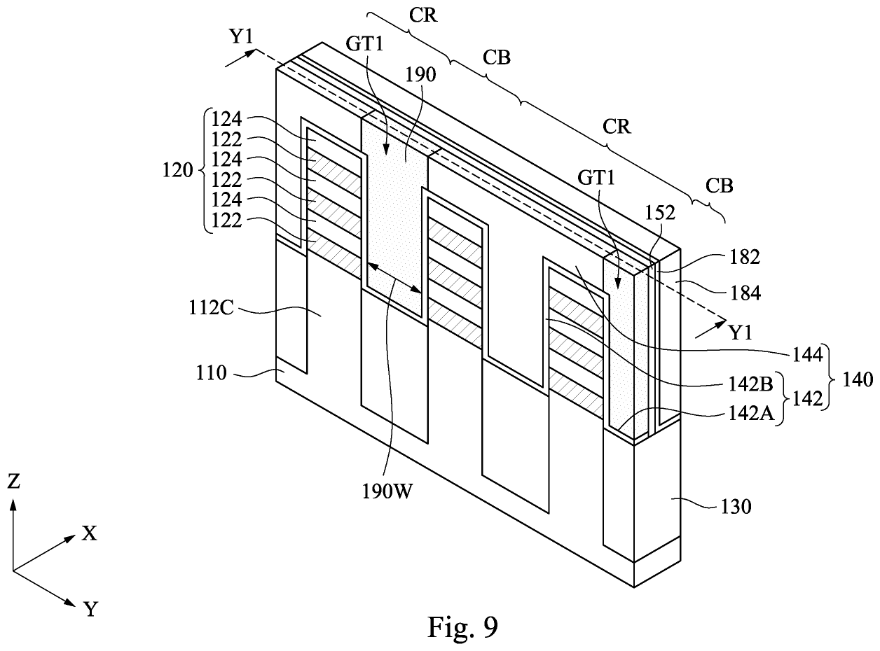

FIGS. 8 and 9 illustrate replacing at least one first portion of the dummy gate electrode layer 144 with a gate isolation structure 190. Referring to FIG. 8, the first portions of the dummy gate electrode 144 over the isolation structure 130 at a boundary region CB between cell regions CR are removed, and second portions of the dummy gate electrode 144 in the cell regions CR remain unremoved. The removal of the first portions of the dummy gate electrode 144 may be performed by using suitable photolithography and etching techniques. For example, a patterned mask is formed over the cell regions CR and exposing the boundary region CB, and materials in the boundary region can be removed by suitable etching techniques. In the illustrated embodiments, the first portions of the dummy gate electrode 144 are removed by using a selective etching process (e.g., selective dry etching, selective wet etching, or a combination thereof) that etches the materials in dummy gate electrode 144 at a faster etch rate than it etches other materials (e.g., the dummy gate dielectric layer 142, the gate spacers 152, the CESL 182 and/or ILD layer 184), thus resulting in gate trenches GT1 between corresponding gate spacers 152 in the boundary region CB, with the portions 142A of the dummy gate dielectric layer 142 exposed in the gate trenches GT1. The gate trench GT1 is formed such that each of the exposed portions 142A has a vertical portion on a sidewall of the fins FS and a horizontal portion on a top surface of the isolation structure 130. And, portions 142B of the dummy gate dielectric layer 142 remains covered by the second portions of the dummy gate electrode layer 144. In the present embodiments, each of the portions 142B have a vertical portion on a sidewall of the fins FS, a horizontal portion on a top surface of the isolation structure 130, and a top portion over a top surface of the fins FS.

Referring to FIG. 9, the gate isolation structures 190 are formed in the first gate trenches GT1. Formation of the gate isolation structures 190 includes depositing a dielectric material into the gate trench GT1, followed by a planarization process. The deposited dielectric material may be SiO₂, SiN, SiCN, SiOC, SiOCN, other low-k dielectric materials (with dielectric constant lower than about 7), the like, or the combination thereof. The dielectric material may be formed by a suitable deposition method, such as CVD, ALD, the like, or the combination thereof. The planarization process (e.g., CMP process) may remove a portion of the dielectric material external to the gate trench GT1 (e.g., higher than a top surface of the ILD layer 184 and top surfaces of the second portions of the dummy gate electrode 144), such that remaining portions of the dielectric material form the gate isolation structures 190. In the boundary region CB, the space between the channel layers 124 above the isolation structure 130 is fully occupied by the gate isolation structures 190, such that cross-sectional areas of the gate metal layers 230 are lowered, thereby reducing gate to SD capacitance. The gate isolation structures 190 may be in direct contact with the portions 142A of the dummy gate dielectric layer 142, respectively. The gate isolation structure 190 may have a width 190 W in a range from about 10 nanometers to about 100 nanometers. If the width 190 W of the gate isolation structure 190 is less than about 10 nanometers, the width 190 W of the gate isolation structure 190 may be too small to be formed by etching process. If the width 190 W of the gate isolation structure 190 is greater than about 100 nanometers, a cell size may be enlarged unnecessarily. In context, the gate isolation structure 190 may also be referred to as a dielectric wall.

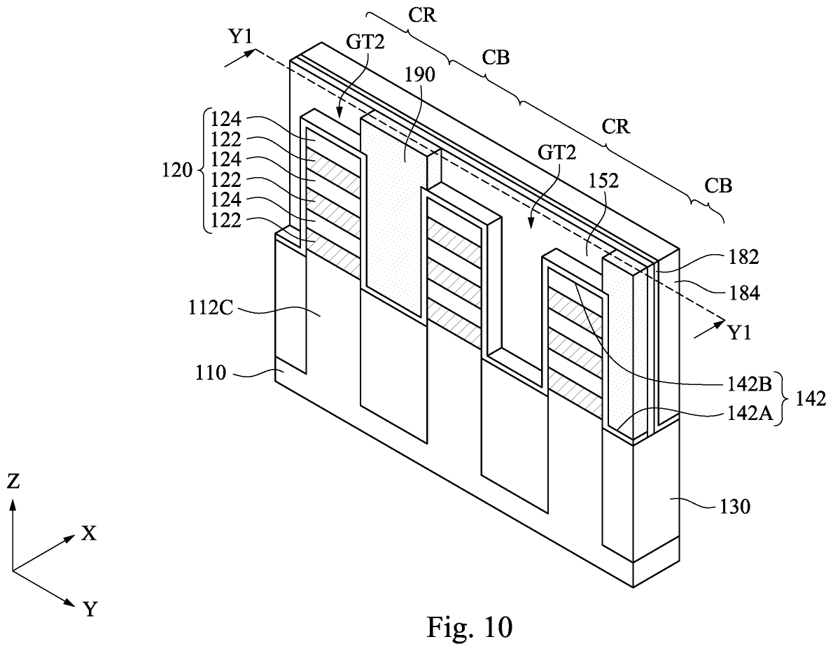

FIGS. 10-13C illustrate replacing second portions of the dummy gate electrode layer 144 with high-k/metal gate structures 200. Referring to FIG. 10, the second portions of the dummy gate electrode 144 in the cell regions CR are removed. The removal of the first portions of the dummy gate electrode 144 may be performed by an etch back process. In the illustrated embodiments, the second portions of the dummy gate electrode 144 are removed by using a selective etching process (e.g., selective dry etching, selective wet etching, or a combination thereof) that etches the materials in dummy gate electrode 144 at a faster etch rate than it etches other materials (e.g., the dummy gate dielectric layer 142, the gate spacers 152, the gate isolation structures 190, the CESL 182 and/or ILD layer 184), thus resulting in gate trenches GT2 between corresponding gate spacers 152 and between the gate isolation structures 190 in the cell region CR, with the portions 142B of the dummy gate dielectric layer 142 exposed in the gate trenches GT2.

Referring to FIGS. 11A and 11B, next, the portions 142B of the dummy gate dielectric layer 142 are removed, followed by removing the sacrificial layers 122. In the illustrated embodiments, the portions 142B of the dummy gate dielectric layer 142 are removed by an oxide removal process, such that a first side of the fins FS including the sacrificial layers 122 (referring to FIG. 10) and the channel layers 124 are exposed in the gate trenches GT2, while a second side of the fins FS including the sacrificial layers 122 (referring to FIG. 10) and the channel layers 124 remain covered by the portions 142A of the dummy gate dielectric layer 142. The oxide removal process may include a dry etch, a wet etch, or the combination thereof. The oxide removal process may use an isotropic etching process. The oxide removal process etches the dummy gate dielectric layer 142 at a faster etch rate than it etches other materials (e.g., the gate spacers 152 and the gate isolation structures 190). Due to the presence of the sacrificial layers 122 and the gate isolation structures 190, the portions 142A of the dummy gate dielectric layer 142 covered by the sacrificial layers 122 and the gate isolation structures 190 is not etched. Subsequently, the sacrificial layers 122 in the gate trenches GT2 are etched by using a selective etching process that etches the sacrificial layers 122 at a faster etch rate than it etches the channel layers 124, thus forming openings O1 between neighboring channel layers 124. In this way, the channel layers 124 become nanosheets suspended over the substrate 110 and between the source/drain epitaxial structures 170. This step is also called a channel release process or “sheet formation” (SHF) process. At this interim processing step, the openings O1 between nanosheets 124 may be filled with ambient environment conditions (e.g., air, nitrogen, etc). In some embodiments, the nanosheets 124 can be interchangeably referred to as nanowires, nanoslabs and nanorings, depending on their geometry. For example, in some other embodiments, the channel layers 124 may be trimmed to have a substantial rounded shape (i.e., cylindrical) due to the selective etching process for completely removing the sacrificial layers 122 (referring to FIG. 10). In that case, the resultant channel layers 124 can be called nanowires.

In some embodiments, the sacrificial layers 122 (referring to FIG. 10) are removed by using a selective wet etching process. In some embodiments, the sacrificial layers 122 are SiGe and the channel layers 124 are silicon allowing for the selective removal of the sacrificial layers 122 (referring to FIG. 10). In some embodiments, the selective wet etching includes an APM etch (e.g., ammonia hydroxide-hydrogen peroxide-water mixture). In some embodiments, the selective removal includes SiGe oxidation followed by a SiGeOₓ removal. For example, the oxidation may be provided by O₃ clean and then SiGeOₓ removed by an etchant such as NH₄OH that selectively etches SiGeOₓ at a faster etch rate than it etches Si. Moreover, because oxidation rate of Si is much lower (sometimes 30 times lower) than oxidation rate of SiGe, the channel layers 124 may remain substantially intact during the channel release process. In some embodiments, both the channel release step and the previous step of laterally recessing sacrificial layers use a selective etching process that etches SiGe at a faster etch rate than etching Si, and therefore these two steps may use the same etchant chemistry in some embodiments. In this case, the etching time/duration of channel release step is longer than the etching time/duration of the previous step of laterally recessing sacrificial layers, so as to completely remove the sacrificial SiGe layers.

FIG. 11C is an enlarged view of a portion of FIG. 11B. After the channel release process, the channel layer 124 may have an end surface 124S, an entirety of which adjoins the portion 142A of the dummy gate dielectric layer 142. And, the portion 142A of the dummy gate dielectric layer 142 extend beyond top and bottom surfaces of the channel layer 124.

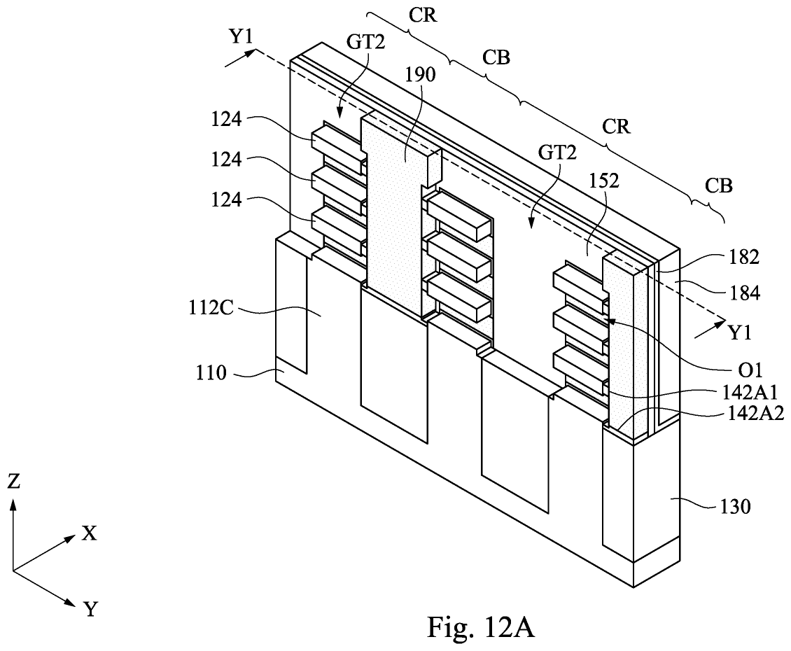

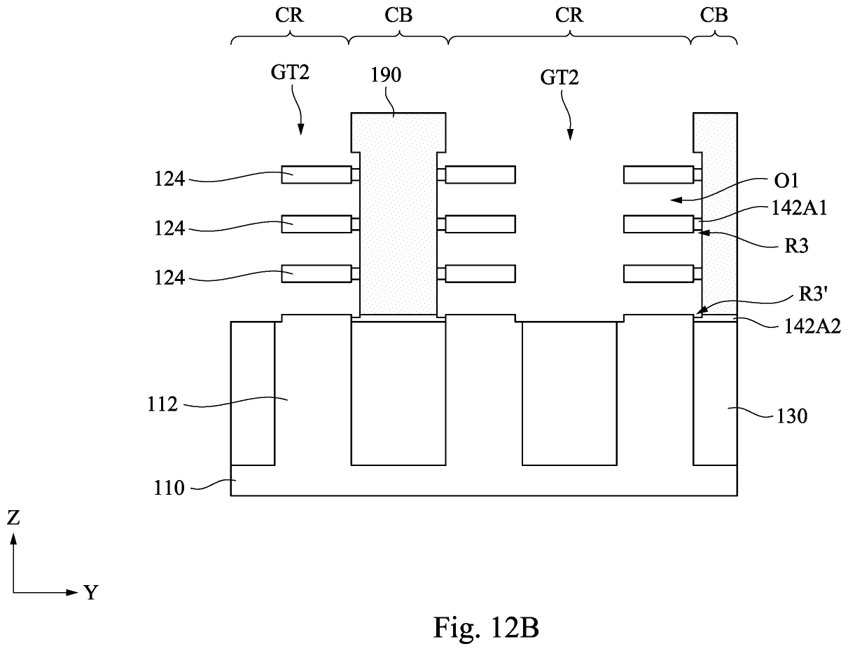

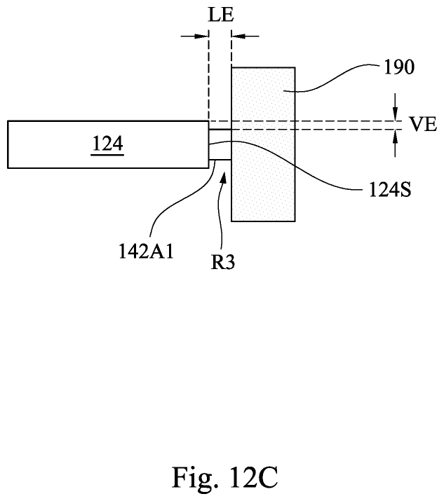

Referring to FIGS. 12A-12B, the portions 142A of the dummy gate dielectric layer 142 (referring to FIGS. 11A-11B) are trimmed, thereby creating spaces for pi-gate subsequently formed. Through the trimming process, each of the portion 142A of the dummy gate dielectric layer 142 (referring to FIGS. 11A-11B) is cut into dielectric elements 142A1 and a dielectric layer 142A2 below the gate isolation structure 190, and a height of the dielectric elements 142A1 is less than a thickness of the channel layer 124. The trimming process may include a dry etch, a wet etch, or the combination thereof. The trimming process may use an isotropic etching process. The isotropic etching process etches the portion 142A of the dummy gate dielectric layer 142 (referring to FIGS. 11A-11B) at a faster etch rate than it etches other materials (e.g., the gate spacers 152 and the gate isolation structures 190). After the trimming process, recesses R3 are formed among the channel layer 124, the gate isolation structure 190, and the dielectric elements 142A1, and recesses R3′ are formed between the portion 112 of the substrate 110 and the dielectric layer 142A2.

FIG. 12C is an enlarged view of a portion of FIG. 12B. The recess R3 may have a suitable width LE defined by the channel layer 124 and the gate isolation structure 190. The width LE is substantially equal to a thickness of the dummy gate dielectric layer 142 (e.g., a thickness of the dielectric elements 142A1 of the dummy gate dielectric layer 142) in FIG. 10. In some embodiments, the width LE is in a range from about 1 nanometer to about 6 nanometers. The etch time of the dry etching process may be controlled such that the recess R3 have a suitable depth VE. In some embodiments, the depth VE is in a range from about 0.1 nanometer to about 2.5 nanometers. If the width LE is greater than about 6 nanometers, or if the depth VE is greater than about 2.5 nanometers, the size of the device may be increased unnecessarily. If the width LE is less than about 1 nanometer, or if the depth VE is less than about 0.1 nanometer, the subsequent formed high-k/metal gate structures may have poor gate control performance, and leakages become large. In some embodiments, the end surface 124S of the channel layer 124 is partially adjoined to the dielectric elements 142A1. And, in some embodiments, the dielectric element 142A1 does not extend beyond the top and bottom surfaces of the channel layer 124.

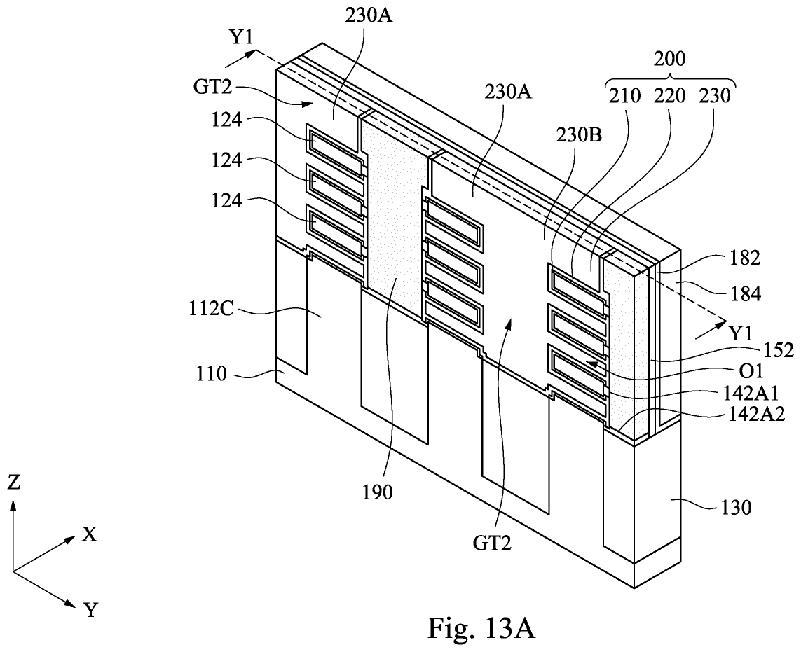

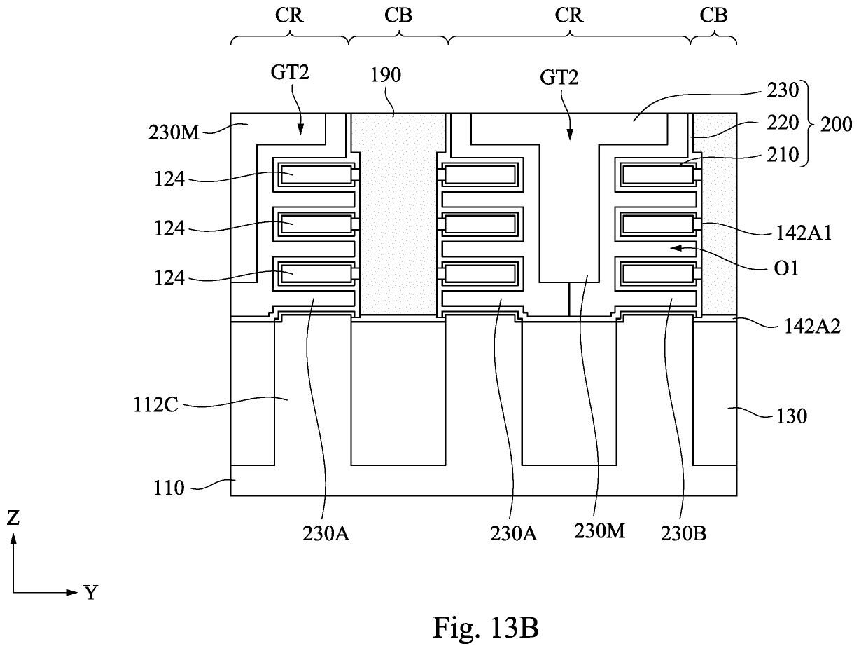

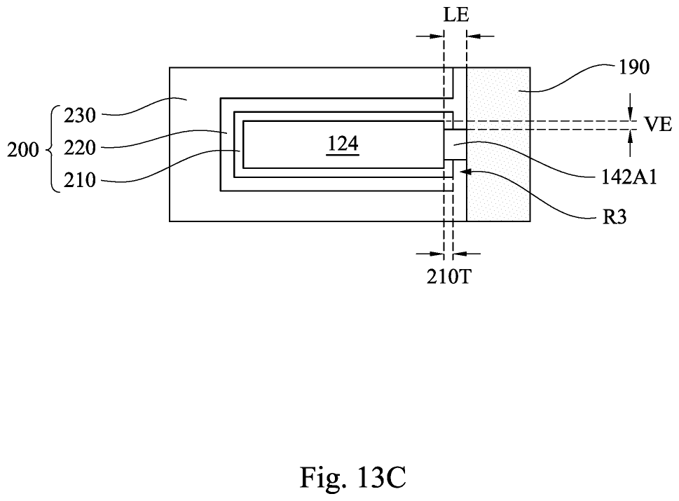

Referring to FIGS. 13A-13B, the high-k/metal gate structures 200 are respectively formed in the gate trenches GT2 to surround each of the nanosheets 124 suspended in the gate trenches GT2. The gate structures 200 may be final gates of GAA FETs. The final gate structure may be a high-k/metal gate stack, however other compositions are possible. In some embodiments, each of the gate structures 200 forms the gate associated with the multi-channels provided by the plurality of nanosheets 124. For example, high-k/metal gate structures 200 are formed within the openings O1 provided by the release of nanosheets 124. In various embodiments, the high-k/metal gate structure 200 includes an interfacial layer 210 formed around the nanosheets 124, a high-k dielectric layer 220 formed around the interfacial layer 210, and a gate metal layer 230 formed around the high-k dielectric layer 220 and filling a remainder of gate trenches GT2. The interfacial layer 210 and the high-k dielectric layer 220 in combination can be referred to as a gate dielectric layer. Formation of the high-k/metal gate structures 200 may include one or more deposition processes to form various gate materials, followed by a CMP processes to remove excessive gate materials, resulting in the high-k/metal gate structures 200 having top surfaces level with a top surface of the ILD layer 184. As illustrated in the cross-sectional view of FIG. 13B, the high-k/metal gate structure 200 surrounds each of the nanosheets 124, and thus is referred to as a gate of a GAA FET.

FIG. 13C is an enlarged view of a portion of FIG. 13B. In some embodiments, the high-k/metal gate structure 200 may extend into the recesses R3, and thus have a pi-gate shape, which is beneficial for short channel control. For example, in the present embodiments, the interfacial layer 210 may extend into the recess R3, and the high-k dielectric layer 220 may extend into the recess R3 and fill a remainder of the recess R3, in which little or no gate metal layer 230 may extend into the recess R3. In some alternative embodiments, the interfacial layer 210 may extend into the recess R3, the high-k dielectric layer 220 may extend into the recess R3, and the gate metal layer 230 (e.g., work function metal layer(s)) may extend into the recess R3 and fill a remainder of the recess R3.

In some embodiments, the interfacial layer 210 is silicon oxide formed on exposed surfaces of semiconductor materials in the gate trenches GT2 by using, for example, thermal oxidation, chemical oxidation, wet oxidation or the like. As a result, surface portions of the nanosheets 124 free of contacting the dielectric elements 142A1 and surface portions of the semiconductor substrate 110 free of contacting the dielectric layer 142A2, exposed in the gate trenches GT2, are oxidized into silicon oxide to form the interfacial layer 210. The interfacial layer 210 may have a thickness 210T less than the width LE of the recess R3. Stated differently, the thickness 210T of the interfacial layer 210 formed by oxidation is less than the thickness of the dummy gate dielectric layer 142 (e.g., a thickness of the dielectric elements 142A1 of the dummy gate dielectric layer 142) formed by deposition in FIG. 10.

In some embodiments, the high-k dielectric layer 220 includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof.

In some embodiments, the gate metal layer 230 includes one or more metal layers. For example, the gate metal layer 230 may include one or more work function metal layers 230A and 230B stacked one over another and a fill metal 230M filling up a remainder of gate trenches GT2. The one or more work function metal layers 230A and 230B in the gate metal layer 230 provide a suitable work function for the high-k/metal gate structures 200. For an n-type GAA FET, the gate metal layer 230 may include one or more n-type work function metal (N-metal) layers. The n-type work function metal may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TIC), aluminum carbide (AIC)), aluminides, and/or other suitable materials. On the other hand, for a p-type GAA FET, the gate metal layer 230 may include one or more p-type work function metal (P-metal) layers. The p-type work function metal may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. The work function metal layer 230A may be one of the n-type and p-type work function metal layers, and the work function metal layer 230B may be the other one of the n-type and p-type work function metal layers. In some embodiments, the fill metal 230M in the gate metal layer 230 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

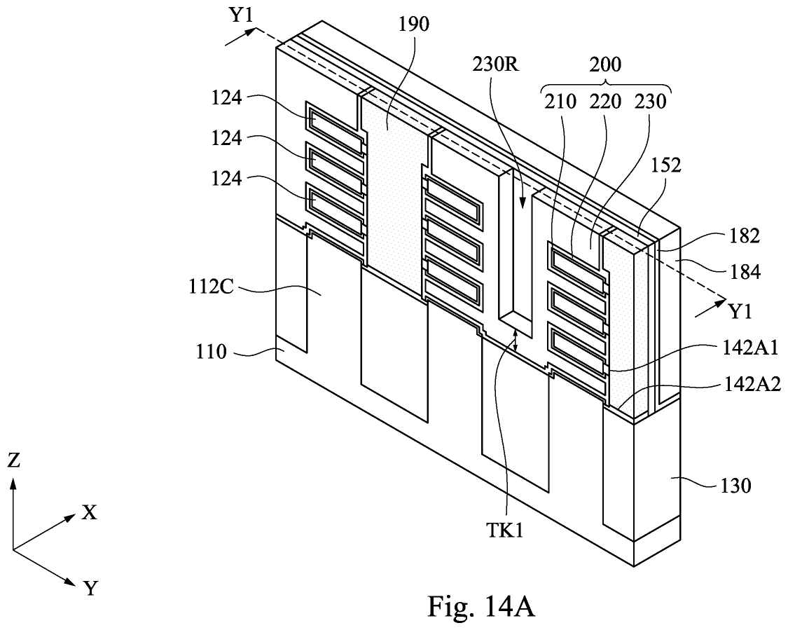

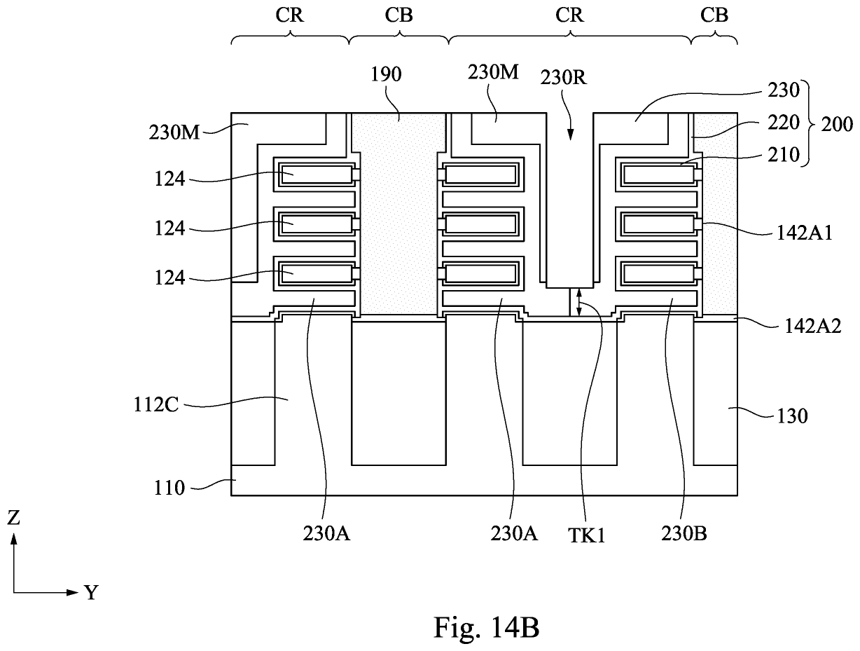

Reference is made to FIGS. 14A and 14B. The gate metal layer 230 is partially recessed, thereby lowering a cross-sectional area of the gate metal layer 230, which is beneficial for reducing the gate to SD capacitance. Stated differently, a recess 230R is formed in the gate metal layer 230. The removal of portions of the gate metal layer 230 may be performed by using suitable photolithography and etching techniques. For example, a patterned mask is formed to define portions of the gate metal layer 230 to be removed through suitable photolithography, and materials exposed by the patterned mask can be removed by suitable etching techniques. The gate metal layer 230 may have a remaining portion below the recess 230R, such that the high-k dielectric layer 220 is not exposed by the recess 230R. A thickness TK1 of the remaining portion of the gate metal layer 230 may be in a range from about 5 nanometers to about 50 nanometers. If the thickness of the remaining portion of the gate metal layer 230 is less than about 5 nanometers, the electrical resistance of the remaining portion of the gate metal layer 230 may be too high to electrically connect two gates. If the thickness of the remaining portion of the gate metal layer 230 is greater than about 50 nanometers, the gate to SD capacitance may not be effectively reduced by lowering a cross-sectional area of the gate metal layer 230. In the present embodiments, the work function metal layers 230A or/and 230B may be exposed by the recess 230R. In some other embodiments, after the formation of the recess 230R, the work function metal layers 230A or/and 230B may be not exposed by the recess 230R.

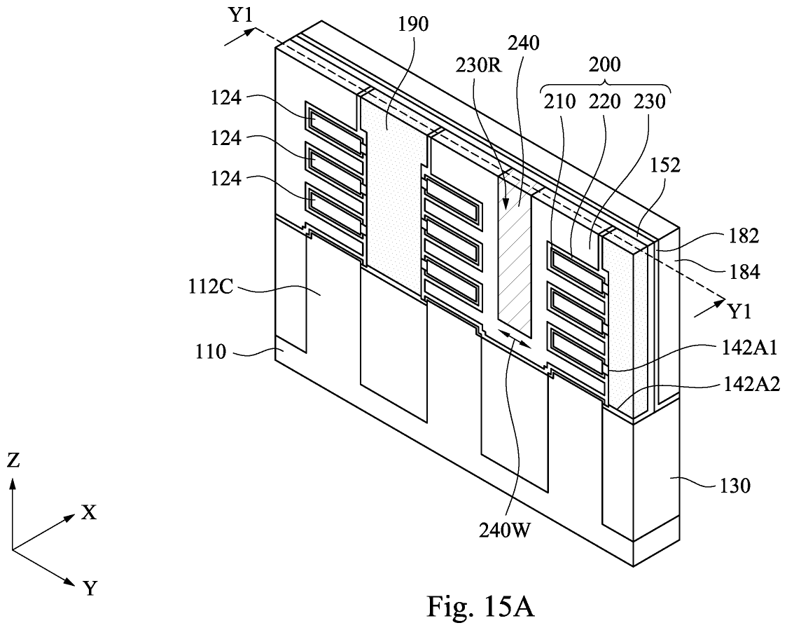

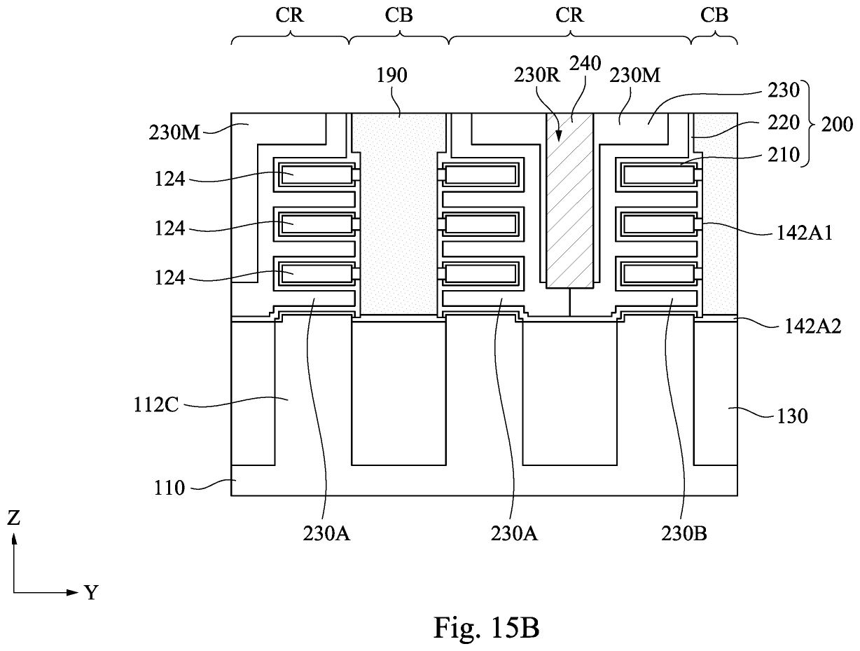

Reference is made to FIGS. 15A and 15B. A dielectric feature 240 is formed in the recess 230R. Formation of the dielectric feature 240 includes depositing a dielectric material into the recess 230R, followed by a planarization process. The dielectric material may include silicon nitride, silicon oxide, SiOC, SiCN, SiOCN, and/or other suitable materials. The planarization process may remove portions of the dielectric material that is external to the recess 230R. Remaining portion of the dielectric material in the recess 230R forms the dielectric feature 240. In the present embodiments, a bottom surface of the dielectric feature 240 is in contact with the work function metal layers 230A and 230B, and sidewalls of the dielectric feature 240 are in contact with the fill metal 230M. In some other embodiments, a bottom surface of the dielectric feature 240 is spaced apart from the work function metal layers 230A and 230B. In the cell region CR, by inserting the dielectric feature 240 into the gate metal layer 230, a cross-sectional area of the gate metal layer 230 is lowered, thereby reducing gate to SD capacitance. The dielectric feature 240 may have a width 240 W in a range from about 5 nanometers to about 30 nanometers. If the width 240 W of the dielectric feature 240 is less than about 5 nanometers, the width 240 W of the dielectric feature 240 may be too small to be formed by etching process. If the width 240 W of the dielectric feature 240 is greater than about 30 nanometers, a cell size may be enlarged unnecessarily.

Reference is made to FIGS. 16A-16C. Source/drain contacts 250 are formed over the source/drain epitaxial structures 170, and then gate contact vias 264G is formed over the gate metal layer 230, and source/drain vias 264SD are formed over the source/drain contacts 250. In some embodiments, source/drain contact holes are first etched through the ILD layer 184 and CESL 182 to expose the source/drain epitaxial structures 170 by using suitable photolithography and etching techniques. Silicide regions (not shown) may be formed on the exposed surfaces of the source/drain epitaxial structures 170 by using a silicidation process. The source/drain contacts 250 may be formed by depositing one or more metal materials (e.g., tungsten, cobalt, copper, the like or combinations thereof) to fill the contact holes by using suitable deposition techniques (e.g., CVD, PVD, ALD, the like or combinations thereof), followed by a CMP process to remove excess metal materials outside the contact holes.

An ILD layer 262 is deposited over the ILD layer 184, the source/drain contacts 250, and the high-k/metal gate structures 200. In some embodiments, the ILD layer 262 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 262 may be deposited by a PECVD process or other suitable deposition technique. In some embodiments, after formation of the ILD layer 262, the integrated circuit device may be subject to a high thermal budget process to anneal the ILD layer 262.

The gate contact vias 264G and the source/drain vias 264SD are formed in the ILD layer 262. In some embodiments, gate via openings and source/drain via openings are first etched through the ILD layer 262 to respectively expose the gate metal layer 230 and source/drain contacts 250 by using suitable photolithography and etching techniques. The gate contact vias 264G and the source/drain vias 264SD may be formed by depositing one or more metal materials (e.g., tungsten, cobalt, copper, the like or combinations thereof) to fill the gate via openings and source/drain via openings by using suitable deposition techniques (e.g., CVD, PVD, ALD, the like or combinations thereof), followed by a CMP process to remove excess metal materials outside the gate via openings and source/drain via openings.

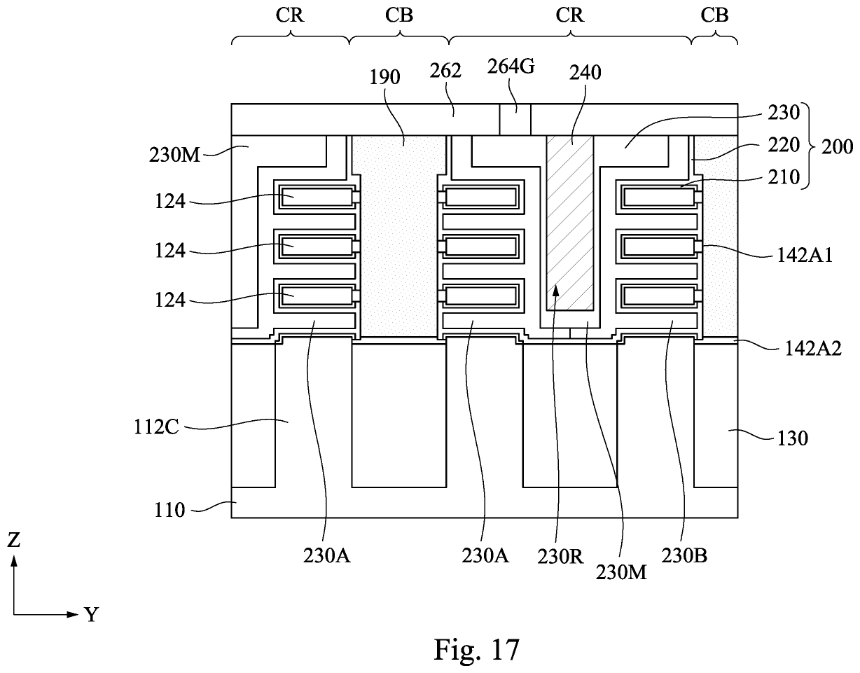

FIG. 17 illustrate a cross-sectional view of an integrated circuit device in accordance with some embodiments. Details of the present embodiments are similar to those illustrated in FIGS. 1-16C, except that the fill metal 230M may have a remaining portion below the recess 230R, such that the work function metal layers 230A and 230B are not exposed by the recess 230R. As a result, a bottom surface of the dielectric feature 240 is in contact with the fill metal 230M, and spaced apart from the work function metal layers 230A and 230B. Other details of the present embodiments are similar to those illustrated above, and thereto not repeated herein.

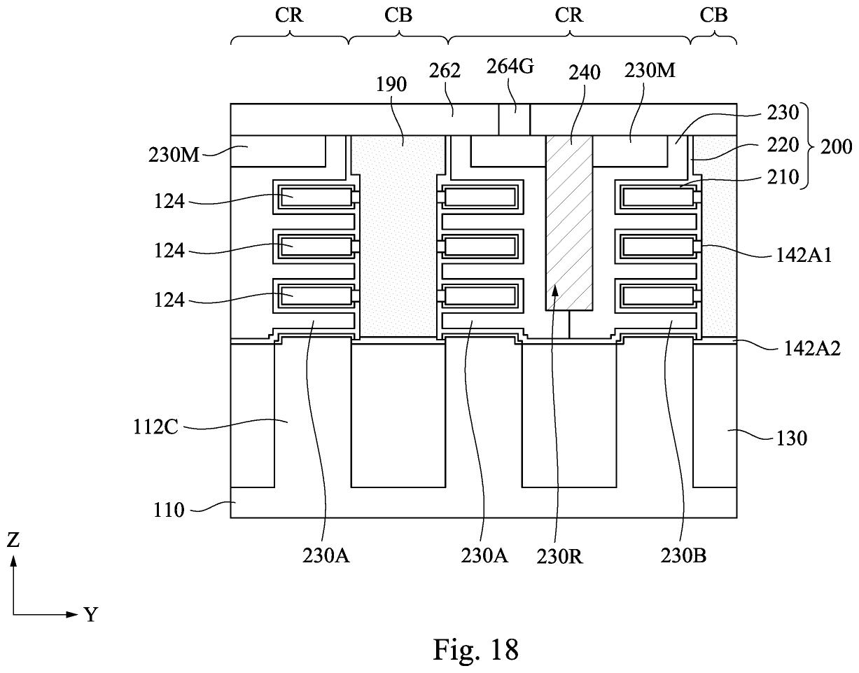

FIG. 18 illustrates a cross-sectional view of an integrated circuit device in accordance with some embodiments. Details of the present embodiments are similar to those illustrated in FIGS. 1-16C, except that a bottom surface of the fill metal 230M is higher than a top surface of the semiconductor layer 124, such that the recess 230R is etched to expose the work function metal layers 230A and 230B at its bottom and sidewalls. As a result, the sidewalls of the dielectric feature 240 are in contact with the work function metal layers 230A and 230B. Other details of the present embodiments are similar to those illustrated above, and thereto not repeated herein.

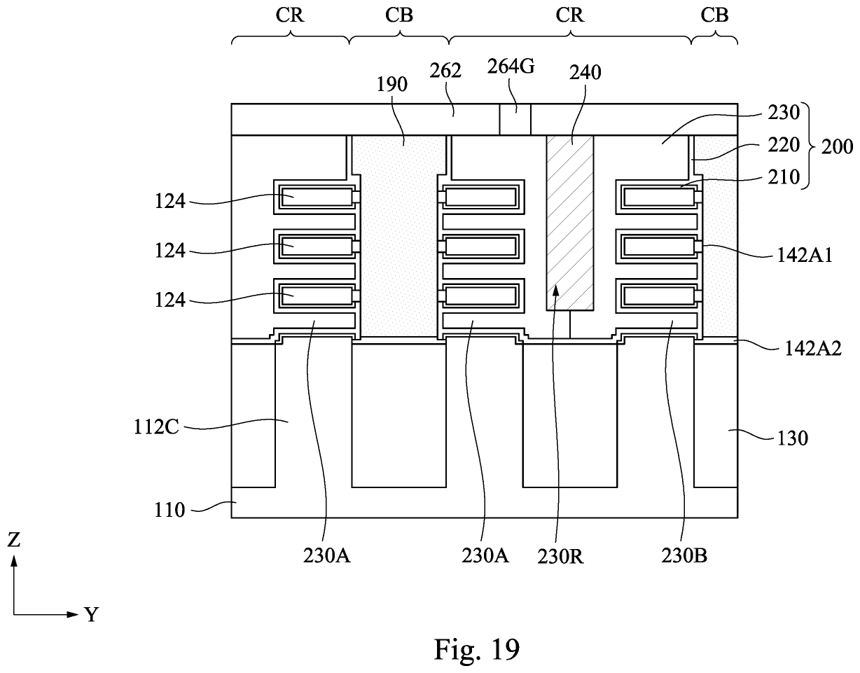

FIG. 19 illustrate a cross-sectional view of an integrated circuit device in accordance with some embodiments. Details of the present embodiments are similar to those illustrated in FIGS. 1-16C, except that an entirety of the gate metal layer 230 is work function metal layers 230A and 230B, with no fill metal therein. As a result, the sidewalls of the dielectric feature 240 are in contact with the work function metal layers 230A and 230B. Other details of the present embodiments are similar to those illustrated above, and thereto not repeated herein.

Based on the above discussions, it can be seen that the present disclosure offers advantages over GAA devices. It is understood, however, that other embodiments may offer additional advantages, and not all advantages are necessarily disclosed herein, and that no particular advantage is required for all embodiments. One advantage is that by inserting a dielectric wall at cell boundary, metal gates in two cell regions are separated from each other, and cross-sectional areas of the metal gates are reduced. Another advantage is that a metal gate in a cell region is recessed and filled with a dielectric feature, such that a cross-sectional area of the metal gate is reduced. By these metal gate area reductions, a gate to source/drain capacitance can be reduced by up to about 10%.

According to some embodiments of the present disclosure, a method for manufacturing an integrated circuit device is provided. The method includes depositing an epitaxial stack over a semiconductor substrate, wherein the epitaxial stack comprises a plurality of first and second semiconductor layers alternatively arranged over the semiconductor substrate; patterning the epitaxial stack to form a first semiconductor fin and a second semiconductor fin; removing the first semiconductor layers in the first and second semiconductor fins, while leaving a first set of the second semiconductor layers in the first semiconductor fin and a second set of the second semiconductor layers in the second semiconductor fin; forming a gate dielectric layer around the first and second sets of the second semiconductor layers; depositing a gate metal layer over the gate dielectric layer; etching a recess in the gate metal layer and between the first set of the second semiconductor layers and the second set of the second semiconductor layers, wherein the gate metal layer has a first portion below the recess; and forming a dielectric feature in the recess of the gate metal layer.

According to some embodiments of the present disclosure, a method for manufacturing an integrated circuit device is provided. The method includes depositing an epitaxial stack over a semiconductor substrate, wherein the epitaxial stack comprises a plurality of first and second semiconductor layers alternatively arranged over the semiconductor substrate; patterning the epitaxial stack to form a semiconductor fin; forming a dummy gate structure over the semiconductor fin, wherein the dummy gate structure comprises a dummy gate dielectric layer and a dummy gate electrode over the dummy gate dielectric layer; removing a first portion of the dummy gate electrode and a first portion of the dummy gate dielectric layer to expose a first side of the semiconductor fin, wherein a second side of the semiconductor fin is covered by a second portion of the dummy gate dielectric layer; removing the first semiconductor layers in the semiconductor fin, while leaving the second semiconductor layers, wherein ends of the second semiconductor layers adjoins the second portion of the dummy gate dielectric layer; after removing the first semiconductor layers in the semiconductor fin, trimming the second portion of the dummy gate dielectric layer; and forming a high-k/metal gate structure around the second semiconductor layers.

According to some embodiments of the present disclosure, an integrated circuit device includes first channel layers, second channel layers, a first gate structure, and a dielectric feature. The first channel layers are vertically spaced apart from each other. The second channel layers are vertically spaced apart from each other. The first gate structure surrounds the first channel layers and the second channel layers. The first gate structure comprises a gate dielectric layer and a gate metal layer over the gate dielectric layer. The dielectric feature is in the first gate structure. The dielectric feature is between the first channel layers and the second channel layers, and the gate metal layer has a first portion below the dielectric feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing an integrated circuit device, comprising:
depositing an epitaxial stack over a semiconductor substrate, wherein the epitaxial stack comprises a plurality of first and second semiconductor layers alternatively arranged over the semiconductor substrate;
patterning the epitaxial stack to form a first semiconductor fin and a second semiconductor fin;
removing the first semiconductor layers in the first and second semiconductor fins, while leaving a first set of the second semiconductor layers in the first semiconductor fin and a second set of the second semiconductor layers in the second semiconductor fin;
forming a gate dielectric layer around the first and second sets of the second semiconductor layers;
depositing a gate metal layer over the gate dielectric layer;
etching a recess in the gate metal layer and between the first set of the second semiconductor layers and the second set of the second semiconductor layers, wherein the gate metal layer has a first portion below the recess; and
forming a dielectric feature in the recess of the gate metal layer.

2. The method of claim 1, wherein forming the dielectric feature is performed such that the dielectric feature is spaced apart from the first semiconductor layers by a second portion of the gate metal layer and spaced apart from the second semiconductor layers by a third portion of the gate metal layer.

3. The method of claim 2, wherein the second portion of the gate metal layer comprises a first-type work function metal layer, and the third portion of the gate metal layer comprises a second-type work function metal layer different from the first-type work function metal layer.

4. The method of claim 1, further comprising:
forming a dummy gate structure over the first and second semiconductor fins; and
removing the dummy gate structure to leave a gate trench, wherein depositing the gate metal layer is performed such that the gate metal layer fills up the gate trench.

5. The method of claim 1, further comprising:
forming a shallow trench isolation (STI) structure between the first semiconductor fin and the second semiconductor fin, wherein etching the recess in the gate metal layer is performed such that the recess is above the STI structure.

6. The method of claim 5, wherein the dielectric feature comprises a dielectric material different from that of the STI structure.

7. The method of claim 1, wherein forming the dielectric feature comprises:
filling the recess of the gate metal layer with a dielectric material; and
planarizing a top surface of the dielectric material with the top surface of the gate metal layer.

8. The method of claim 1, wherein forming the dielectric feature is performed such that a bottom surface of the dielectric feature is below a top surface of a topmost one of the first semiconductor layers.

9. The method of claim 1, wherein etching the recess in the gate metal layer is performed such that the gate dielectric layer is not exposed by the recess.

10. A method for manufacturing an integrated circuit device, comprising:
depositing an epitaxial stack over a semiconductor substrate, wherein the epitaxial stack comprises a plurality of first and second semiconductor layers alternatively arranged over the semiconductor substrate;
patterning the epitaxial stack to form a semiconductor fin;
forming a dummy gate structure over the semiconductor fin, wherein the dummy gate structure comprises a dummy gate dielectric layer and a dummy gate electrode over the dummy gate dielectric layer;
removing a first portion of the dummy gate electrode and a first portion of the dummy gate dielectric layer to expose a first side of the semiconductor fin, wherein a second side of the semiconductor fin is covered by a second portion of the dummy gate dielectric layer;
removing the first semiconductor layers in the semiconductor fin, while leaving the second semiconductor layers, wherein ends of the second semiconductor layers adjoins the second portion of the dummy gate dielectric layer;
after removing the first semiconductor layers in the semiconductor fin, trimming the second portion of the dummy gate dielectric layer; and
forming a high-k/metal gate structure around the second semiconductor layers.

11. The method of claim 10, further comprising:
prior to removing the first portion of the dummy gate electrode and the first portion of the dummy gate dielectric layer, replacing a second portion of the dummy gate electrode at the second side of the semiconductor fin with a dielectric wall, wherein the dielectric wall is spaced apart from the semiconductor fin by the second portion of the dummy gate dielectric layer.

12. The method of claim 11, wherein trimming the second portion of the dummy gate dielectric layer is performed such that at least one recess is formed among the dielectric wall, the trimmed second portion of the dummy gate dielectric layer, and at least one of the second semiconductor layers, and forming the high-k/metal gate structure is performed such that the high-k/metal gate structure has at least one portion in the at least one recess.

13. The method of claim 11, wherein trimming the second portion of the dummy gate dielectric layer is performed such that a sidewall of the dielectric wall adjacent the semiconductor fin is exposed.

14. The method of claim 11, wherein trimming the second portion of the dummy gate dielectric layer is performed such that the second portion of the dummy gate dielectric layer is cut into a plurality of dielectric elements spaced apart from each other, and the dielectric elements are respectively between the dielectric wall and the second semiconductor layers.

15. The method of claim 14, wherein forming the high-k/metal gate structure is performed such that a high-k dielectric layer of the high-k/metal gate structure is in contact with the dielectric elements.

16. The method of claim 14, wherein forming the dummy gate structure is performed such that the dummy gate dielectric layer has a first thickness, forming the high-k/metal gate structure is performed such that an interfacial layer of the high-k/metal gate structure has a second thickness less than the first thickness.

17. An integrated circuit device, comprising:
a plurality of first channel layers vertically spaced apart from each other;
a plurality of second channel layers vertically spaced apart from each other;
a first gate structure surrounding the first channel layers and the second channel layers, wherein the first gate structure comprises a gate dielectric layer and a gate metal layer over the gate dielectric layer; and
a dielectric feature in the first gate structure, wherein the dielectric feature is between the first channel layers and the second channel layers, and the gate metal layer has a first portion below the dielectric feature.

18. The integrated circuit device of claim 17, wherein the dielectric feature is spaced apart from the first channel layers by a second portion of the gate metal layer and spaced apart from the second channel layers by a third portion of the gate metal layer, the second portion of the gate metal layer comprises a first-type work function metal layer, and the third portion of the gate metal layer comprises a second-type work function metal layer different from the first-type work function metal layer.

19. The integrated circuit device of claim 17, further comprising:
a plurality of third channel layers vertically spaced apart from each other, wherein the first channel layers is between the second channel layers and the third channel layers;
a second gate structure surrounding the third channel layers; and
a dielectric wall spacing the first gate structure apart from the second gate structure.

20. The integrated circuit device of claim 19, wherein the gate dielectric layer of the first gate structure comprises a high-k dielectric layer, and a portion of the high-k dielectric layer is between the dielectric wall and the first channel layers.
